(19) United States
(12) Patent Application Publication
(10) Pub. No.: US 2025/0297368 A1
(43) Pub. Date: Sep. 25, 2025

(54) METHODS FOR ETCHING METAL OXIDE LAYERS EMPLOYING CYCLICAL ETCHING PROCESSES, AND ASSOCIATED METHODS FOR FORMING METAL OXIDE LAYERS

(71) Applicant: ASM IP Holding B. V., Almere (NL)

(72) Inventors: Charles Dezelah, Helsinki (FI); Patricio Eduardo Romero, Boutersem (BE); Bart Vermeulen, Dresden (DE); Alessandra Leonhardt, Sipoo (FI)

(21) Appl. No.: 19/081,881

(22) Filed: Mar. 17, 2025

Related U.S. Application Data
(60) Provisional application No. 63/568,466, filed on Mar. 22, 2024.

(51) Int. Cl. C23F 1/12; C23C 16/40; C23C 16/455; C23C 16/56

(52) U.S. Cl. CPC C23F 1/12; C23C 16/405; C23C 16/45525; C23C 16/56

(57) ABSTRACT

Methods for etching a metal oxide layer on a surface of a substrate in a reaction chamber by a cyclical etching process are disclosed. The cyclical etching processes include repeated etching cycles, with each etching cycle including, contacting the metal oxide layer with a gas-phase modifier reactant and contacting the metal oxide layer with a gas-phase halogen reactant. Methods for forming metal oxide layers are also disclosed, such methods include depositing a metal oxide layer on a device structure, thermally treating the deposited metal oxide, and subsequently removing a portion of the deposited metal oxide layer by cyclical etching processes.

### CROSS-REFERENCE TO RELATED APPLICATION(S)

This Application claims the benefit of U.S. Provisional Application 63/568,466 filed on Mar. 22, 2024, the entire contents of which are incorporated herein by reference.

### FIELD

The present disclosure generally relates to the field of semiconductor processing methods, and to the field of device and integrated circuit manufacture. More particularly, the present disclosure relates to methods for etching a metal oxide layer by cyclical etching processes. In addition, the present disclosure also relates to methods for forming metal oxide layers, and particularly methods for forming crystalline hafnium zirconium oxide layers.

### BACKGROUND

The manufacture of semiconductor devices relies on the precise formation of material layers with controlled thicknesses and surface topographies. To obtain such layers, etching of selected materials, and/or portions thereof, may be performed. Etch processes for removing portions of a material layer can commonly be categorized as either wet-etch processes or dry-etch processes.

As the name suggests, wet-etch processes employ liquid etchants, wherein a material layer is immersed in, or otherwise contacted with, a corrosive liquid which can isotropically etch the material layer equally in all directions simultaneously. Although wet-etch processes can rapidly remove material using relatively simple equipment, such processes tend to be difficult to control, both in terms of the etch rate and the end point detection, but can also be limited when etch directionality (i.e., isotropic vs anisotropic) of the material layer is desired.

In contrast, dry-etch methods generally employ gaseous reactants in either a plasma state or a non-plasma state. Plasma based etch processes commonly utilize a gas energized into an excited plasma state to produce reactive species which can be directed to and etch the material layer. However, common plasma based etch processes, such as reactive ion etching, can lack the etch selectivity and precision needed when the amount of material to be removed from the material layer is in the nanometer scale and below. In addition, the high energy reactive species produced within the plasma can have detrimental effects on the unetched portions of the material layer and/or those layers proximate to the material layer.

In non-plasma etch methods, vapor-phase reactants are commonly used that react with the surface of the material layer to produce gaseous reaction products. The reaction products are removed from the substrate surface, leading to etching of the material layer. Vapor-phase etching methods such as chemical vapor etching (CVE) and atomic layer etching (ALEt) have received increasing attention in recent years due to a wide variety of potential applications in the semiconductor industry. However, such chemical etching processes can lack specificity to certain materials and therefore there is a need for improved chemical etch processes.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In accordance with examples of the disclosure a method for etching a metal oxide layer on a surface of a substrate in a reaction chamber is provided. An example method includes etching the metal oxide layer employing a cyclical etching process including one or more etching cycles. In accordance with examples of the disclosure, each etching cycle includes contacting the metal oxide layer with a gas-phase modifier reactant of a formula SiR1R2R3L, where all R groups (R1, R2, and R3) are independently selected from hydrogen, C1 to C6 alkyl groups and silyl groups, a halogen, or an alkoxy group of a formula OR4, where R4 is a C1 to C6 alkyl group, and where L is a ligand, and contacting the metal oxide layer with a gas-phase halogen reactant.

In some embodiments, the ligand is selected from a group consisting of cyclopentadienyl, beta-diketonate, amidinate, amidate, guanidinate, pyrazole, pyrrole, or dialkylamide.

In some embodiments, the gas-phase modifier reactant includes a trialkylsilyl group.

In some embodiments, the trialkylsilyl group is a trimethylsilyl group.

In some embodiments, the gas-phase modifier reactant includes at least one of N-trimethylsilyl-3,5,-dimethylpyrazole, N-trimethylsilyl-3,5,-di-tert-butylpyrazole, N-trimethylsilylpyrrole, and N-trimethylsilyl-2,3,4,5-tetramethylpyrrole.

In some embodiments, the gas-phase halogen reactant includes one or more of chlorine gas, hydrochloric acid, phosphorous pentachloride, phosphorous trichloride, phosphoryl chloride, thionyl chloride, sulfuryl chloride, disulfur dichloride, acetyl chloride, oxalyl chloride, N-chlorosuccinimide, and t-butyl hypochlorite.

In some embodiments, the metal oxide layer is a transition metal oxide selected from a group consisting of a zirconium oxide, a hafnium oxide, or a hafnium zirconium oxide.

In some embodiments, the metal oxide layer is initially contacted with the gas-phase halogen reactant prior to contacting the metal oxide layer with the gas-phase modifier reactant.

In some embodiments, the cyclical etching process is an atomic layer etching process.

In accordance with examples of the disclosure a method for atomic layer etching a hafnium zirconium oxide layer is provided. An example method includes seating a substrate including the hafnium zirconium oxide layer into a reaction chamber, and performing an atomic layer etching process including a plurality of repeated etching cycles. In such examples each etching cycle includes introducing into the reaction chamber a gas-phase modifier reactant comprising a trialkylsilyl group and a detachable group, and introducing into the reaction chamber a gas-phase halogen reactant.

In some embodiments, the trialkylsilyl group is a trimethylsilyl group.

In some embodiments, the detachable group is a ligand selected from a group consisting of cyclopentadienyl, beta-diketonate, amidinate, amidate, guanidinate, pyrazole, pyrrole, or dialkylamide.

In some embodiments, the gas-phase modifier reactant includes one or more of N-trimethylsilyl-3,5,-dimethylpyrazole, N-N-trimethylsilyl-3,5,-di-tert-butylpyrazole, N-trimethylsilylpyrrole, and N-trimethylsilyl-2,3,4,5-tetramethylpyrrole.

In some embodiments, the gas-phase halogen reactant includes one or more of chlorine gas, hydrochloric acid, phosphorous pentachloride, phosphorous trichloride, phosphoryl chloride, thionyl chloride, sulfuryl chloride, disulfur dichloride, acetyl chloride, oxalyl chloride, N-chlorosuccinimide, and t-butyl hypochlorite.

In some embodiments, the hafnium zirconium oxide layer is initially contacted with the gas-phase halogen reactant prior to contacting the hafnium zirconium oxide layer with the gas-phase modifier reactant.

In some embodiments, the hafnium zirconium oxide layer has a zirconium content equal to or greater than 50 atomic-%.

In accordance with examples of the disclosure a method of forming a hafnium zirconium oxide layer on a device structure is provided. An example method includes depositing an amorphous hafnium zirconium oxide layer on a surface of the device structure supported within a reaction chamber. In accordance with examples of the disclosure, the method also includes thermally treating the amorphous hafnium zirconium oxide layer to form a crystalline hafnium zirconium oxide layer. In accordance with examples of the disclosure, the methods also includes etching a portion of the crystalline hafnium zirconium oxide layer by a cyclical etching process comprising one or more etching cycles. In such examples each etching cycle includes contacting the crystalline hafnium zirconium oxide layer with a gas-phase modifier reactant of a formula SiR1R2R3L, where all R groups (R1, R2 and R3) are independently selected from hydrogen, C1 to C6 alkyl groups and silyl groups, a halogen, or an alkoxy group of a formula OR4, where R4 is a C1 to C6 alkyl group, and where L is a ligand, contacting the crystalline hafnium zirconium oxide layer with a gas-phase halogen reactant.

In some embodiments, the amorphous hafnium zirconium oxide layer is deposited by a conformal cyclical deposition process.

In some embodiments, the conformal cyclical deposition process comprises an atomic layer deposition process.

In some embodiments, the amorphous hafnium zirconium oxide layer has an average layer thickness equal to or greater than 5 nm.

In some embodiments, thermally treating the amorphous hafnium zirconium oxide layer includes annealing the amorphous hafnium zirconium oxide layer at a temperature between 300° C. and 500° C.

In some embodiments, etching a portion of the crystalline hafnium zirconium oxide layer by the cyclical etching process leaves a remaining portion of the crystalline hafnium zirconium oxide layer having an average layer thickness less than 5 nanometers.

In some embodiments, the remaining portion of the crystalline hafnium zirconium oxide layer has a capacitance equal to or greater than 100 fF/μm².

In some embodiments, the remaining portion of the crystalline hafnium zirconium oxide layer has a dielectric constant greater than 20.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary process for etching a metal oxide layer in accordance with one or more embodiments of the disclosure.

FIG. 2 illustrates an exemplary process for forming a metal oxide layer in accordance with one or more embodiments of the disclosure.

FIG. 3 illustrates a structure including a substrate and a device structure in accordance with one or more embodiments of the disclosure.

FIG. 4 illustrates a structure formed in accordance with one or more embodiments of the disclosure.

FIG. 5 illustrates an additional structure formed in accordance with one or more embodiments of the disclosure.

FIG. 6 illustrates a further structure formed in accordance with one or more embodiments of the disclosure.

FIG. 7 illustrates an exemplary gas-phase modifier reactant in accordance with one or more embodiments of the disclosure.

FIG. 8 illustrates an exemplary ligand of a gas-phase modifier reactant in accordance with one or more embodiments of the disclosure.

FIG. 9 illustrates an additional exemplary ligand of a gas-phase modifier reactant in accordance with one or more embodiments of the disclosure.

FIG. 10 illustrates a further exemplary ligand of a gas-phase modifier reactant in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “gas” can include material that is a gas at normal temperature and pressure (NTP), a vaporized solid and/or a vaporized liquid, and can be constituted by a single gas or a mixture of gases, depending on the context. A reactant may be provided to the reaction chamber in the gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three- dimensional materials, nanoparticles or even partial or full molecular layers or partial or full atomic layers or clusters of atoms and/or molecules. A layer may comprise material or a layer with pinholes, which may be at least partially continuous.

The term “cyclic etch process” or “cyclical etch process” can refer to the sequential introduction of reactants into a reaction chamber to etch at least a portion of a material layer and includes processing techniques such as cyclical chemical vapor etch and atomic layer etching (ALEt). Atomic layer etching (ALEt) is a comparable technique to atomic layer deposition (ALD), in that separated pulses of one or more reactants are utilized. However, rather than depositing material as in ALD, in ALEt thin layers of material are controllably removed using sequential reaction steps. In ALEt processes the sequential reaction steps are self-limiting. In contrast to conventional continuous etching, ALEt typically utilizes one or more etching cycles to remove material.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

A number of example materials are given throughout the embodiments of the current disclosure, it should be noted that the chemical formulas given for each of the example materials should not be construed as limiting and that the non-limiting example materials given should not be limited by a given example stoichiometry.

The embodiments of the present disclosure include methods for etching metal oxide layers and particularly transition metal oxide layers. In accordance with examples of the disclosure, methods are provided for etching transition metal oxide layers including one or more of hafnium (Hf) and zirconium (Zr), such as, hafnium oxide layers, zirconium oxide layers, and hafnium zirconium oxide layer. Metal oxide layers including hafnium/zirconium have been demonstrated as important materials for use in current and future semiconductor applications. As a non-limiting example, hafnium zirconium oxide layer have been demonstrated as useful materials in ferroelectric based memory devices. However, controlled etching of metal oxides including hafnium/zirconium has proven challenging, particularly thermal etching processes (i.e., etching in the absence of plasma generated reactive species).

The embodiments of the present disclosure also include methods for forming metal oxide layers. In particular, methods are provided for forming thin crystalline transition metal oxide layers including one or more of hafnium and zirconium. Hafnium zirconium oxide layer can be employed as high capacitance/high dielectric layers in device structures such as MIM (metal-insulator-metal) storage capacitors and as layers in decoupling capacitors. However, forming hafnium zirconium oxide layer with high capacitance/dielectric properties has proven challenging, especially at low temperatures/thermal budgets.

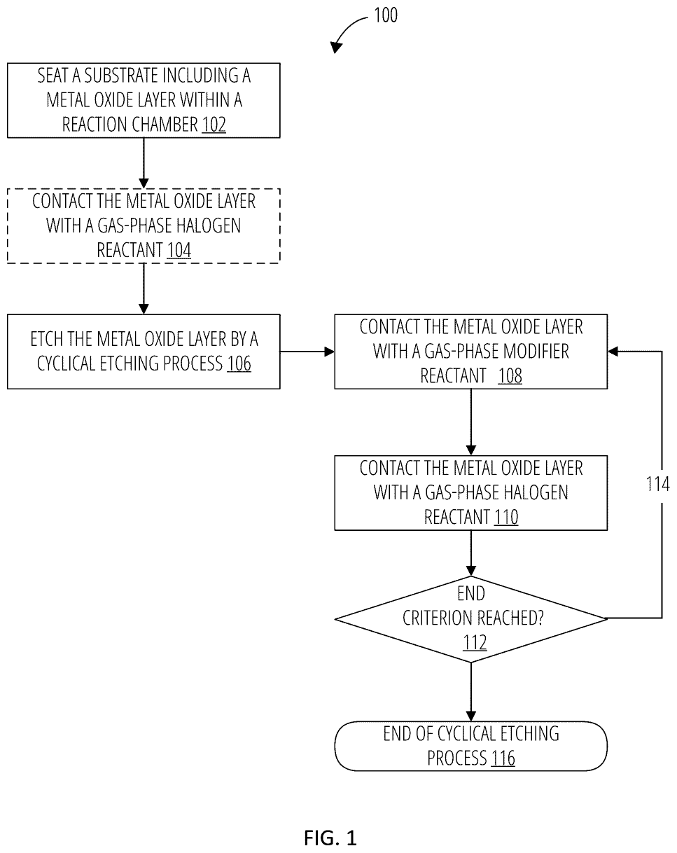

The etching methods of the present disclosure include cyclical etching processes, such as, for example, cyclical chemical vapor etch processes and atomic layer etching processes for etching a metal oxide layer. An exemplary cyclical etching processes of the present disclosure is illustrated and described briefly with reference to process 100 of FIG. 1 and will described in greater detail below.

In accordance with examples of the disclosure, process 100 includes disposing a substrate including a metal oxide layer (e.g., a hafnium zirconium oxide layer) within a reaction chamber configured for performing cyclical etching processes (step 102). The metal oxide layer is then contacted with an initial gas-phase halogen reactant to halogenate the surface of the metal oxide layer. In some embodiments, the initial halogenation of the metal oxide layer can be performed by an optional surface preparation step (step 104) which comprises contacting the surface of the metal oxide layer with a gas-phase halogen reactant. In alternative embodiments, the initial halogenation of the metal oxide layer is achieved by sub-step 110 of the cyclical etching process 106 which also comprises contacting the surface of the metal oxide layer with a gas-phase halogen reactant, as described in more detail below. Upon forming the halogenated surface on the metal oxide layer the cyclical etching process 106 is performed to remove a portion of the metal oxide layer. As illustrated in process 100 each etching cycle (as indicated by cycle loop 114) of the cyclical etching process 106 comprises the sub-steps of, contacting the halogenated surface of the metal oxide layer with a gas-phase modifier reactant (sub-step 108) and subsequently contacting the metal oxide layer with a gas-phase halogen reactant. In accordance with examples of the disclosure, the introduction of the gas-phase modifier reactant into the reaction chamber (in sub-step 108) results in a conversion of the halogenated surface of the metal oxide layer to a modified surface. Subsequently, the introduction of the gas-phase halogen reactant into the reaction chamber (in sub-step 110) results in the removal of a portion of the metal oxide layer as a result of the reaction between the gas-phase halogen reactant and the modified surface of the metal oxide layer. In some embodiments of the disclosure, the introduction of the gas-phase halogen reactant into the reaction chamber (in sub-step 110) not only removes a portion of the metal oxide layer but also halogenates the newly exposed surface of the remaining portion of the metal oxide layer. In other words, the gas-phase halogen reactant introduced in sub-step 110 of the cyclical etching process 106 can act as both an etchant and a halogenating agent when contacting the metal oxide layer. Having removed a portion of the metal oxide layer the cyclical etching process 106 continues with a decision block 112 based on a predetermined end criterion. For example, if the end criterion is not satisfied (e.g., the thickness of removed material is insufficient) then the cyclical etching process 106 is repeated (as indicated by cyclical loop 114) and sub-steps 108, 110, and 112 are repeated one or more times until the end criterion is satisfied and the etch process terminates (step 116).

In greater detail, process 100 includes seating a substrate comprising a metal oxide layer within a reaction chamber (step 102). In accordance with examples of the disclosure, the substrate can include one or more transition metal oxide layers. In some embodiments, the one or more transition metal oxide layer layers are disposed on a substrate, such as, for example, a silicon substrate.

In accordance with examples of the disclosure, the metal oxide layer is a binary transition metal oxide. In such examples, the metal oxide layer is a hafnium oxide or a zirconium oxide, where hafnium oxide and zirconium oxide are materials that are represented by chemical formulas that includes hafnium (Hf), and oxygen (O), or zirconium (Zr) and oxygen (O), respectively. In some embodiments, the hafnium oxide/zirconium oxide may not include significant proportions of elements other than hafnium/zirconium, and oxygen. In such embodiments the hafnium oxide/zirconium oxide consists essentially of HfO or ZrO. A layer consisting of HfO or ZrO may include an acceptable amount of impurities, such as hydrogen, carbon, chlorine, and/or the like that may originate from the precursors used in forming the HfO or ZrO.

In accordance with additional examples of the disclosure, the metal oxide layer is a ternary transition metal oxide. In such examples, the ternary transition metal oxide is a hafnium zirconium oxide, where hafnium zirconium oxide is a material that is represented by a chemical formula that includes hafnium (Hf), zirconium (Zr), and oxygen (O), and the abbreviation HZO refers to a material comprising these elements, without limiting the stoichiometry of the material. In some embodiments, the hafnium zirconium oxide may not include significant proportions of elements other than hafnium, zirconium, and oxygen. In such embodiments the hafnium zirconium oxide consists essentially of HfZrO. A layer consisting of hafnium zirconium oxide may include an acceptable amount of impurities, such as hydrogen, carbon, chlorine, and/or the like that may originate from the precursors used in forming the HZO.

In some embodiments the metal oxide layer comprises a crystalline layer, such as a crystalline hafnium zirconium oxide layer, for example. In such embodiments, the crystalline structure of the transition metal oxide layer (e.g., HfO, ZrO, HZO) exhibits long range ordering. It should be appreciated that a crystalline metal oxide layer may not be a perfect single crystal but may also comprise various defects, stacking faults, atomic substitutions, and the like, as long as the crystalline material exhibits long range ordering. In some embodiments, the hafnium zirconium oxide is a ferroelectric material.

In some embodiments, the substrate may comprise multiple HZO layers composed of hafnium, zirconium, and oxygen, with substantially the same stoichiometry. In some embodiments, the substrate may comprise multiple HZO layers composed of hafnium, zirconium, and oxygen with differing stoichiometry. In some embodiments, the stoichiometry of the ternary transition metal oxide layer is about AₓB_{y}O₂, where A is a first transition metal (e.g., Hf), B is a second transition metal (e.g., Zr), O is oxygen, and x+y=1. In some embodiments, the atomic proportions of the elements are about A_{0.5}B_{0.5}O₂, such as Hf_{0.5}Zr_{0.5}O₂. In some embodiments, the stoichiometry of the hafnium and the zirconium in the HZO layer is about 1:1.

In accordance with examples of the disclosure, the transition metal oxide layer is disposed on a substrate. In some embodiments the substrate comprises a silicon substrate. In some embodiments, the substrate may comprise other materials in addition to silicon, such as those described above.

Turning again to process 100 of FIG. 1, step 102 includes seating the substrate in a reaction chamber. The reaction chamber can be configured for performing all, or a portion, of the remaining steps of process 100. Reactors and associated reaction chamber(s) capable of the cyclical etching processes of the present disclosure may include reaction chambers configured to perform cyclical chemical etch processes, such as, for example reaction chambers configured to perform cyclical chemical vapor etching and atomic layer etching, as well as reaction chambers configured for the introduction of reactants in a cyclical manner. For example, in some embodiments, the cyclical etching processes of the present disclosure can be performed within a semiconductor processing apparatus configured for atomic layer deposition as well as atomic layer etching and cyclical chemical vapor etching.

In some embodiments, the reaction chamber employed for performing the cyclical etching processes can be, or include, a reaction chamber of an atomic layer deposition reactor system configured to perform one or more cyclical etching processes. The reaction chamber can be a standalone reaction chamber or part of a cluster tool. The reaction chamber may be a batch processing tool. In some embodiments, a flow-type reactor may be utilized. In some embodiments, a showerhead-type reactor may be utilized. In some embodiments, a space divided reactor may be utilized. In some embodiments, a high-volume manufacturing-capable single wafer reactor may be utilized. In other embodiments, a batch reactor comprising multiple substrates may be utilized. For embodiments in which a batch reactor is used, the number of substrates may be in the range of 10 to 200, or 50 to 150, or even 100 to 130. The reactor can be configured as a thermal reactor-with no plasma excitation apparatus.

In accordance with examples of the disclosure, process 100 includes heating the substrate to a suitable temperature for performing the cyclical etching processes. In some embodiments, the substrate is heated to a substrate temperature of less than 400° C., less than 300° C., less than 250° C., less than 200° C., less than 150° C., less than 100°° C., less than 50° C., or between 50° C. and 400° C. In some embodiments, the cyclical etching processes are performed at an ambient temperature. The ambient temperature may be, for example from about 20° C. to about 30° C.

In accordance with examples of the disclosure, process 100 can be performed in reduced pressure. In some embodiments, the pressure within the reaction chamber is between 1 mTorr and 760 Torr, or between 0.5 Torr and 30 Torr, such as 10 Torr, 15 Torr or 20 Torr. In some embodiments, the pressure within the reaction chamber is less than 500 Torr, or between 0.1 Torr and 500 Torr, or between 1 Torr and 200 Torr, or between 1 Torr and 20 Torr. In some embodiments, the pressure within the reaction chamber is less than 10 Torr, less than 50 Torr, less than 200 Torr, or less than 300 Torr.

In accordance with examples of the disclosure, process 100 includes an initial halogenation of the surface of the metal oxide layer. The initial halogenation of the surface of the metal oxide layer is performed to enable subsequent reaction(s) upon the introduction of the gas-phase modifier reactant. In accordance with examples of the disclosure, the initial halogenation of the metal oxide layer can be achieved by either performing optional step 104 or alternatively sub-step 110 of the cyclical etching process 106.

In some embodiments, the initial halogenation of the metal oxide layer is achieved by performing an optional pre-etch surface preparation process (optional step 104). In such embodiments, a gas-phase halogen reactant (described in greater detail below) is introduced into the reaction chamber and contacts the native surface of the metal oxide layer forming a halogenated surface (i.e., a surface including halogen species).

In some embodiments, the initial halogenation of the metal oxide layer is achieved by performing sub-step 110 of the cyclical etching process 106. In such embodiments, the optional step 104 can be omitted and the cyclical etching process 106 initiates with sub-step 110 (rather than sub-step 108 as illustrated in exemplary process 100 of FIG. 1). In such embodiments, a gas-phase halogen reactant (described in greater detail below) is introduced into the reaction chamber and contacts the native surface of the metal oxide layer, halogenating the surface, as described above. Having initiated the cyclical etching process 106 with sub-step 110, the cyclical etching process 106 continues with the sequential introduction of the gas-phase modifier reactants (sub-step 108) and the gas-phase halogen reactant (sub-step 110) as described in greater detail below.

In accordance with examples of the disclosure, the optional pre-etch surface preparation process (optional step 104) and sub-step 110 of the cyclical etching process 106 both comprise the introduction of a gas-phase modifier reactant into the reaction chamber and contacting the metal oxide layer with the gas-phase halogen reactant. In some embodiments, optional step 104 and sub-step 110 can employ the same gas-phase halogen reactant(s). In some embodiment, optional step 104 and sub-step 110 can employ different gas-phase halogen reactant(s). In some embodiments, the gas-phase halogen reactant employed in the initial halogenation of the surface of the transition metal oxide layer is a chlorinating agent.

The duration of providing the gas-phase halogen reactant into the reaction chamber pre-etch (via step 104 or sub-step 110) may be, for example, from 5 seconds to 20 minutes. The duration of providing gas-phase halogen reactant into the reaction chamber pre-etch (i.e., the initial halogenation pulse time) is selected based on the process, tool and other factors. In some embodiments, the duration of providing the gas-phase halogen reactant into the reaction chamber is from 5 seconds to 2 minutes, from 5 seconds to 90 seconds, or from 5 seconds to 60 seconds. In some embodiments, the duration of providing the gas-phase halogen reactant into the reaction chamber is from 15 seconds to 5 minutes, from 15 seconds to 3 minutes, from 15 seconds to about 2 minutes, or from 10 seconds to 90 seconds. In some embodiments, the duration of providing the gas-phase modifier reactant into the reaction chamber is longer than 5 seconds, or longer than 10 seconds, or longer than 30 seconds, or longer than 60 seconds. In some embodiments, the duration of providing the gas-phase halogen reactant into the reaction chamber is shorter than 15 minutes, or shorter than 10 minutes, or shorter than 5 minutes, or shorter than 3 minutes, or shorter than 60 seconds, or shorter than 30 seconds.

Upon completion of the initial halogenation step (optional step 104 or sub-step 110) the reaction chamber can be purged to remove any excess gas-phase halogen reactant and any reaction products, if present. In some embodiments, the purge time after the initial halogenation step is from 0.1 seconds to 120 seconds, from 0.1 seconds to 60 seconds, from 0.1 seconds to 30 seconds, from 0.1 seconds to 10 seconds, from 0.1 seconds to 5 seconds, from 0.1 seconds to 2 seconds, from 0.1 seconds to 1 second, or from 0.1 seconds to 0.5 seconds. In some embodiments, the purge time after the initial halogenation step is less than 60 seconds, less than 30 seconds, less than 10 seconds, less than 4 seconds, less than 1 seconds, or less than 0.5 seconds.

Process 100 (FIG. 1) continues with the cyclical etching process 106. In accordance with examples of the disclosure, the cyclical etching process 106 comprises one or more etching cycles, each cycling comprising, contacting the metal oxide layer with a gas-phase modifier reactant (sub-step 108) and contacting the metal oxide layer with a gas-phase halogen reactant. Details regarding the chemistries of the gas-phase modifier reactant and the gas-phase halogen reactant are described in greater detail below.

The duration of providing the gas-phase halogen reactant (sub-step 108) into the reaction chamber and providing the providing the gas-phase modifier reactant (sub-step 110) into the reaction chamber can be, for example, from about 5 seconds to about 20 minutes. The duration of providing the gas-phase halogen/modifier reactants into the reaction chamber is selected based on the process, tool and other factors. In some embodiments, the duration of providing the gas-phase halogen/modifier reactants into the reaction chamber is between 5 seconds and 2 minutes, between 5 seconds and 90 seconds, or between 5 seconds and 60 seconds. In some embodiments, the duration of providing the gas-phase halogen/modifier reactants into the reaction chamber is between 15 seconds and 5 minutes, between 15 seconds and 3 minutes, between 15 seconds and 2 minutes, or between 10 seconds and 90 seconds. In some embodiments, the duration of providing the gas-phase halogen/modifier reactants into the reaction chamber is longer than 5 seconds, longer than 10 seconds, longer than 30 seconds, or longer than 60 seconds. In some embodiments, the duration of providing the gas-phase halogen/modifier reactants into the reaction chamber is shorter than 15 minutes, shorter than 10 minutes, shorter than 5 minutes, shorter than 3 minutes, shorter than 60 seconds, or shorter than 30 seconds.

Upon completion of each sub-step (e.g., 108, 110) of the cyclical etching process 106 the reaction chamber can be purged to remove any excess reactants and any reaction products. In some embodiments, the purge time is from 0.1 seconds to 120 seconds, from 0.1 seconds to 60 seconds, from 0.1 seconds to 30 seconds, from 0.1 seconds to 10 seconds, from 0.1 seconds to 5 seconds, from 0.1 seconds to 2 seconds, from 0.1 seconds to 1 second, or from 0.1 seconds to 0.5 seconds. In some embodiments, the purge time is shorter than 60 seconds, shorter than 30 seconds, shorter than 10 seconds, shorter than 4 seconds, shorter than 1 seconds, or shorter than 0.5 seconds.

In accordance with examples of the disclosure, sub-step 108 and sub-step 110 can be repeated as illustrated by cycle loop 114. Further, sub-step 108 and sub-step 110 can be initiated and/or terminated in any order. Yet further, cyclical etching process 106 can include one or more (e.g., 1-10 or 1-5) repeated performances of sub-step 108 and/or sub-step 110 prior to proceeding to the next sub-step (e.g., 108, 110, 112) of the cyclical etching process 106. In addition, the cyclical etching process 106 can include addition sub-steps which can be performed within each etching cycle or within selected etching cycles.

In some embodiments of the disclosure, the cyclical etching process 106 comprises at least 5 etching cycles. In some embodiments, the cyclical etching process 106 comprises at least 10, or at least 50 etching cycles. In some embodiments, the cyclical etching process 106 comprises at least 100 etching cycle. In some embodiments, the cyclical etching process 106 comprises at least 200, at least 300, or at least 500 etching cycle. In some embodiments, the cyclical etching process 106 comprises from 5 to 500 etching cycles. In some embodiments, the cyclical etching process 106 comprises from 5 to 100 etching cycles, such as from 5 to 50 etching cycles, or from 10 to 100 etching cycles, or from 50 to 100 etching cycles. In some embodiments, the cyclical etching process 106 comprises from 50 to 500 etching cycles, such as from 50 to 200 etching cycles, or from 100 to about 500 etching cycles. In some embodiments, the cyclical etching process 106 comprises from 100 to 500 etching cycles.

In some embodiments of the disclosure, the cyclical etching process 106 is repeated until a desired end criterion is reached as illustrated in FIG. 1 by the decision block 112. In some embodiments, the end criterion of decision block 112 is based on performing a set number of etching cycles. For example, for a given set of etching process conditions, each etching cycle can have a well-defined etch rate per etching cycle. Therefore the number of etching cycles performed to remove a desired amount of the metal oxide layer can readily be determined. In some embodiments, the end criterion of decision block 112 is be based upon the amount of the metal oxide layer removed. For example, the cyclical etching process 106 (and associated etching apparatus) can employ end point detection systems to terminate the cyclical etching process 106 when it determines a set amount of the metal oxide layer has been removed.

In accordance with examples of the disclosure, the metal oxide layer (e.g., HfO, ZrO, HZO) is etched at a rate from about 0.1 Å to about 5 Å per etching cycle, such as at a rate from 0.1 Å to 1.0 Å per etching cycle. In some embodiments, the metal oxide layer is etched at a rate from 0.1 Å to 0.5 Å per etching cycle, or at a rate from 0.2 Å to 0.5 Å per etching cycle. In some embodiments, the metal oxide layer is etched at a rate from 0.1 Å to 0.3 Å per etching cycle.

In accordance with examples of the disclosure, the metal oxide layer (e.g., HfO, ZrO, HZO) can have an initial thickness (pre-etch) between 8 nm and 10 nm, or between 6 nm and 12 nm, or between 5 nm and 15 nm. In some embodiments, the metal oxide layer is a hafnium zirconium oxide layer having an initial thickness (pre-etch) of less than 20 nm, or less than 16 nm, or less than 12 nm, or less than 8 nm, or less than 5 nm, or between 5 nm and 20 nm. In some embodiments, the metal oxide layer is a hafnium zirconium oxide layer having an initial thickness (pre-etch) of greater than 5 nm, or greater than 8 nm, or greater than 10 nm, or greater than 12 nm, or greater than 15 nm, or between 5 nm and 15 nm.

In some embodiments the cyclical etching process 106 comprises an atomic layer etching process (ALEt). In ALEt processes thin layers of the metal oxide layer (e.g., a hafnium zirconium oxide layers) are controllably removed using sequential reaction steps which are self-limiting. Therefore, in some embodiments, the cyclical etching processes of the present disclosure are self-limiting processes. Thus, in accordance with examples of the disclosure, a method for atomic layer etching (ALEt) a hafnium zirconium oxide layer is disclosed herein. In such examples the ALEt process comprises, providing a substrate comprising a hafnium zirconium oxide layer into a reaction chamber, and performing an atomic layer etching process. In accordance with examples of the disclosure, the atomic layer etching processes of the present disclosure include a plurality of repeated etching cycles, where each etching cycle comprises, introducing into the reaction chamber a gas-phase modifier reactant comprising a trialkylsilyl group and a detachable group (as described in greater detail below), and introducing into the reaction chamber a gas-phase halogen reactant. In such examples, a purge cycle can be performed after completion of each sub-step of the atomic layer etching process, i.e., upon completion of sub-step 108 and upon completion of sub-step 110, as described above.

In some embodiments, the ALEt processes of the present disclosure are performed in a plasma-free environment, i.e., without the introduction of reactive species generated from a plasma. In such embodiments, the atomic layer etching processes of the present disclosure are thermal atomic layer etching processes.

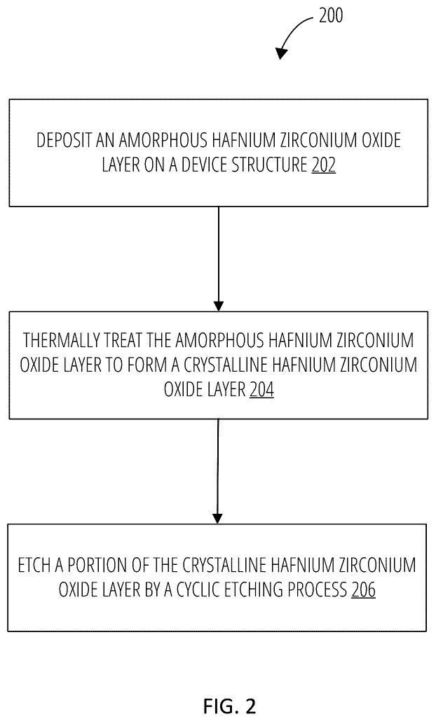

The embodiments of the present disclosure also include methods of forming metal oxide layers and particularly hafnium zirconium oxide layers. In some embodiments, methods are disclosed for forming thin crystalline hafnium zirconium oxide layers with high capacitance/dielectric properties. As previously outlined, hafnium zirconium oxide layers can be employed as high capacitance layers in device structures such as, for example, metal-insulator-metal (MIM) capacitors (e.g., in 3D DRAM devices) and decoupling capacitors, among other advanced applications. An exemplary method for forming a hafnium zirconium oxide layer is illustrated and described briefly with reference to process 200 of FIG. 2 and will described in greater detail below.

In accordance with examples of the disclosure, process 200 includes, depositing an amorphous hafnium zirconium oxide layer on a device structure (step 202). The amorphous hafnium zirconium oxide layer is subsequently subjected to a thermal treatment to convert the amorphous hafnium zirconium oxide layer to a crystalline hafnium zirconium oxide layer (step 204). Process 200 also includes etching a portion of the crystalline hafnium zirconium oxide layer by a cyclical etching process comprising one or more etching cycles (step 206) to leave a remaining portion of crystalline hafnium zirconium oxide.

In greater detail, process 200 includes seating a substrate comprising a device structure within a reaction chamber and depositing an amorphous hafnium zirconium oxide layer on the device structure (step 202).

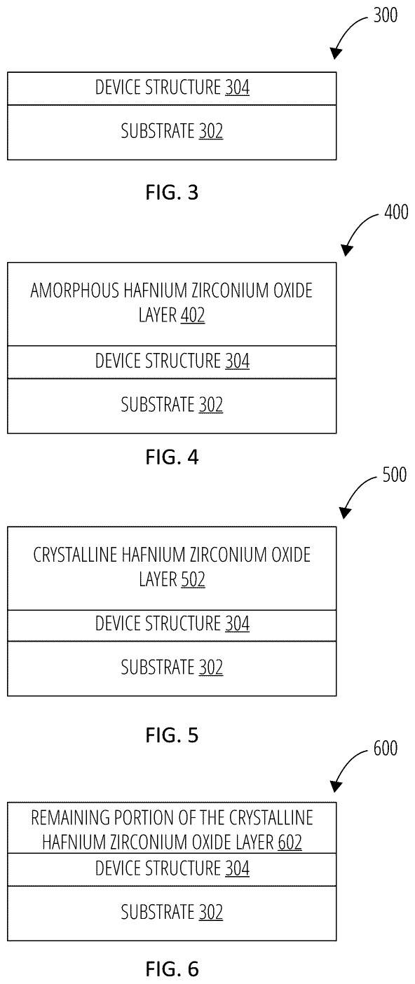

In accordance with examples of the disclosure, the substrate can comprise a patterned substrate that includes a plurality of device structures formed into and/or onto a surface of the substrate. For example, the patterned substrates may comprise device structure which are partially fabricated device structures such as, for examples, transistors elements, memory elements, and the like. The patterned substrate can include a plurality of device structures forming a non-planar surface which may comprise structures extending up from the main surface of the substrate and/or structures extending into the surface of the substrate. The plurality of device structures forming the non-planar surface can include high aspect ratio features, such as high aspect ratio 3D structures, as are commonly employed in some memory applications. Such high aspect ratio features may have an aspect ratio (height: width) which may be greater than 2:1, or greater than 5:1, or greater than 10:1, or greater than 25:1, or greater than 50:1, or even greater than 100:1. As a non-limiting example, FIG. 3 illustrates a structure 300 including a substrate 302 (such as silicon, for example) with a device structure 304 (e.g., a layer containing comprising a plurality of partially fabricated device structures) disposed on the substrate 302.

In accordance with examples of the disclosure, step 202 of process 200 (FIG. 2) includes depositing an amorphous hafnium zirconium oxide layer on the substrate, and particular on the devices structures on/in the substrate. For example, FIG. 4 illustrate a structure 400 which comprises structure 300 (of FIG. 3) with an amorphous hafnium zirconium oxide layer 402 deposited on (e.g., over) the device structure 304.

In some embodiments, the amorphous hafnium zirconium oxide layer is deposited conformally employing a cyclical deposition process, such as an atomic layer deposition process, for example. As a non-limiting example, an atomic layer deposition process for depositing the amorphous hafnium zirconium oxide layer on the substrate can include one or more repetitions of a deposition cycle including: introducing a hafnium precursor, such as tetrakis (dimethylamido) hafnium (TDMAHf) (e.g., TDMAHf) into a reaction chamber, purging the reaction chamber to remove any unreacted precursor and byproducts, introducing an oxygen reactant (such as, water, ozone, hydrogen peroxide, and the like) to react with the hafnium precursor thereby forming a layer of hafnium oxide, again purging the reaction chamber to remove any unreacted precursor and byproducts, introducing a zirconium precursor, such as tetrakis (dimethylamido) zirconium (TDMAZr) into the reaction chamber, again purging the reaction chamber to remove any unreacted precursor and byproducts, introducing an oxygen reactant (either the same as the previous oxygen reactant or an alternative oxygen reactant) to react with the zirconium precursor thereby forming a zirconium oxide, and finally purging the chamber to remove any unreacted oxygen source and byproducts. The exemplary deposition cyclical provided can be repeated until the desired thickness of the amorphous hafnium zirconium oxide layer is deposited on the substrate.

In accordance with examples of the disclosure, the conformal cyclical deposition process employed for deposited the amorphous hafnium zirconium oxide layer can be repeated to form an amorphous hafnium zirconium oxide layer 402 having an average layer thickness equal to or greater than 5 nm, or greater than 8 nm, or greater than 10 nm, or greater than 12 nm, or greater than 15 nm, or between 5 nm and 15 nm. In some embodiments, the amorphous hafnium zirconium oxide layer 402 has a zirconium content equal to or greater than 50 atomic-%, or greater than 60 atomic-%, or greater than 70 atomic-%, or greater than 80 atomic-%, or greater than 90 atomic-%, or greater than 95 atomic-%. In some embodiments, the stoichiometry of the amorphous hafnium zirconium oxide layer is about AₓB_{y}O₂, where A is hafnium, B is zirconium, O is oxygen, and x+y=1. In some embodiments, the atomic proportions of the elements in the amorphous hafnium zirconium oxide layer is about A_{0.5}B_{0.5}O₂, such as Hf_{0.5}Zr_{0.5}O₂. In some embodiments, the stoichiometry of the hafnium and the zirconium in the amorphous hafnium zirconium oxide layer is about 1:1. In some embodiments, the amorphous hafnium zirconium oxide layer can be Zr rich or Hf rich.

It should be noted that the cyclical deposition process for depositing an amorphous hafnium zirconium oxide layer described above is provided as an exemplary process, and further processes for depositing hafnium zirconium oxide layers by cyclical deposition processes techniques are in disclosed greater detail in U.S. patent application Ser. No. 18/319,933, filed May 18, 2023, the entire disclosure of which is incorporated herein by reference for all purposes.

Process 200 of FIG. 2 also includes thermally treating the amorphous hafnium zirconium oxide layer to form a crystalline hafnium zirconium oxide layer (step 204). For example, FIG. 5 illustrate a structure 500 which comprises structure 400 (of FIG. 4) after the thermal treatment and the formation of the crystalline hafnium zirconium oxide layer 502.

In accordance with examples of the disclosure, the step of thermally treating the amorphous hafnium zirconium oxide layer (step 204) can include subjected the substrate with the amorphous hafnium zirconium oxide layer thereon to an annealing step. For example, the amorphous hafnium zirconium oxide layer can be annealed in a substantially inert annealing ambient comprising a noble gas. Other suitable annealing ambients include oxygen-containing ambients such as O₂-containing ambients. Suitably, the anneal can be carried out at an annealing temperature of at least 300° C. to at most 500° C., or of at least 350° C. to at most 450° C., for example at a temperature of around 400° C. Therefore, in some embodiments, thermally treating the amorphous hafnium zirconium oxide layer comprises annealing the amorphous hafnium zirconium oxide layer at a temperature between 300° C. and 500° C.

Process 200 of FIG. 2 also includes, etching a portion of the crystalline hafnium zirconium oxide layer by a cyclical etching process comprising one or more etching cycles (step 206). The cyclical etching process employed for etching a portion of the crystalline hafnium zirconium oxide layer can include those processes previously described above with reference to process 100 of FIG. 1. Therefore, in accordance with examples of the disclosure, etching a portion of the crystalline hafnium zirconium oxide layer can comprise performing one or more etching cycles, where each etching cycle comprises: contacting the crystalline hafnium zirconium oxide layer with a gas-phase modifier reactant of a formula SiR1R2R3L, where all R groups (R1, R2 and R3) are independently selected from hydrogen, C1 to C6 alkyl groups and silyl groups, a halogen, or an alkoxy group of a formula OR4, where R4 is a C1 to C6 alkyl group, and where L is a ligand, and contacting the crystalline hafnium zirconium oxide layer with a gas-phase halogen reactant (as described previously). For example, FIG. 6 illustrate a structure 600 which comprises the structure 500 (of FIG. 5) after the etching a portion of the crystalline hafnium zirconium oxide layer 502 thereby leaving a remaining portion of the crystalline hafnium zirconium oxide layer 602.

In accordance with examples of the disclosure, the remaining portion of the crystalline hafnium zirconium oxide layer 602 has an average layer thickness of less than 5 nm, or less than 4 nm, or less 3 nm, or less than 2 nm, or less than 1 nm, or between 1 nm and 5 nm. In some embodiments, the remaining portion of the crystalline hafnium zirconium oxide layer 602 has a zirconium content equal to or greater than 50 atomic-%, or greater than 60 atomic-%, or greater than 70 atomic-%, or greater than 80 atomic-%, or greater than 90 atomic-%, or greater than 95 atomic-%. In some embodiments, the stoichiometry of the remaining portion of the crystalline hafnium zirconium oxide layer 602 is about AₓB_{y}O₂, where A is hafnium, B is zirconium, O is oxygen, and x+y=1. In some embodiments, the atomic proportions of the elements in the remaining portion of the crystalline hafnium zirconium oxide layer 602 is about A_{0.5}B_{0.5}O₂, such as Hf_{0.5}Zr_{0.5}O₂. In some embodiments, the stoichiometry of the hafnium and the zirconium in the remaining portion of the crystalline hafnium zirconium oxide layer 602 is about 1:1.

In accordance with examples of the disclosure, the remaining portion of the crystalline hafnium zirconium oxide layer 602 has a capacitance equal to or greater than or greater than 100 fF/μm². In some embodiments, the remaining portion of the crystalline hafnium zirconium oxide layer 602 has a capacitance equal to or greater than or greater than 100 fF/μm² and an average layer thickness of less than 5 nm, or less than 4 nm, or less 3 nm, or less than 2 nm, or less than 1 nm, or between 1 nm and 5 nm.

In accordance with examples of the disclosure, the remaining portion of the crystalline hafnium zirconium oxide layer 602 has a dielectric constant equal to or greater than 20. In some embodiments, the remaining portion of the crystalline hafnium zirconium oxide layer 602 has a dielectric constant equal to or greater than 20 and an average layer thickness of less than 5 nm, or less than 4 nm, or less 3 nm, or less than 2 nm, or less than 1 nm, or between 1 nm and 5 nm.

In accordance with examples of the disclosure, one or more gas-phase halogen reactants are introduced into the reaction chamber during the execution of process 100 of FIG. 1. In such examples, a gas-phase halogen reactant (e.g., a first gas-phase halogen reactant) is employed in the initial halogenation of the transition metal oxide layer (via optional step 104 or sub-step 110) and a gas-phase halogen reactant (e.g., a second gas-phase halogen reactant) is employed in the cyclical etching process 106 during sub-step 110. In some embodiments, the first gas-phase halogen reactant and the second gas-phase halogen reactant are the same. In some embodiments, the first gas-phase halogen reactant and the second gas-phase halogen reactant are the different.

In accordance with examples of the disclosure, a gas-phase halogen reactant is employed in the initial halogenation of the transition metal oxide layer, i.e., the first gas-phase halogen reactant. In such examples, the gas-phase halogen reactant reacts with the native surface of the transition metal oxide layer resulting in a halogenated surface comprising a plurality of halogen species. In some embodiments, the gas-phase halogen reactant comprises a halogenating agent. In some embodiments, the gas-phase halogen reactant (i.e., the first gas-phase halogen reactant) comprises a chlorinating agent. In some embodiments, the chlorinating agent is selected from a group consisting of chlorine gas, phosphorous pentachloride, phosphorous trichloride, phosphoryl chloride, thionyl chloride, sulfuryl chloride, disulfur dichloride, acetyl chloride, oxalyl chloride, N-chlorosuccinimide, t-butyl hypochlorite.

In accordance with further examples of the disclosure, a gas-phase halogen reactant is employed in the cyclical etching process 106 and acts as both an etchant and a halogenating agent, i.e., the second gas-phase halogen reactant. For example, the gas-phase halogen reactant utilized in sub-step 110 of the cyclical etching process 106 reacts with a modified surface of the transition metal oxide layer to etch a portion of the transition metal oxide layer. In addition, the gas-phase halogen reactant utilized in sub-step 110 of the cyclical etching process 106 reacts with the newly exposed surface of the transition metal oxide layer (i.e., after the overlying portion of the transition metal oxide layer is etched) to halogenate the new the surface of the transition metal oxide layer. Therefore, In accordance with examples of the disclosure, the gas-phase halogen reactant introduced into the reaction chamber during sub-step 110 of the cyclical etching process 106 (i.e., the second gas-phase halogen reactant) behaves as both an etchant and a halogenating agent.

In some embodiments of the disclosure, the gas-phase halogen reactant comprises at least one halide (X). In some embodiments, the gas-phase halogen reactant comprises at least one of fluorine (F), chlorine (CI), bromine (Br), or iodine (I). In some embodiments the gas-phase halogen reactant comprises chlorine (CI).

In some embodiments the gas-phase halogen reactant is selected from the group consisting of chlorine gas, phosphorous pentachloride, phosphorous trichloride, phosphoryl chloride, thionyl chloride, sulfuryl chloride, disulfur dichloride, acetyl chloride, oxalyl chloride, N-chlorosuccinimide, t-butyl hypochlorite.

In some embodiments, the gas-phase halogen reactant comprises a C—X bond. In some embodiments, the gas-phase halogen reactant comprises a C—Cl bond. In some embodiments, the gas-phase halogen reactant is an acyl halide. In some embodiments, the gas-phase halogen reactant is oxalyl chloride. In some embodiments, the gas-phase halogen reactant is acetyl chloride.

In some embodiments, the gas-phase halogen reactant comprises a S—X bond. In some embodiments, the gas-phase halogen reactant comprises a S—Cl bond. In some embodiments, the gas-phase halogen reactant is thionyl chloride. In some embodiments, the gas-phase halogen reactant is sulfuryl chloride. In some embodiments, the gas-phase halogen reactant is an alkyl sulfonyl chloride. In some embodiments, the gas-phase halogen reactant is disulfur dichloride, S₂Cl₂. In some embodiments, the gas-phase halogen reactant is sulfur dichloride, SCl₂.

In some embodiments, the gas-phase halogen reactant comprises a P—X bond. In some embodiments, the gas-phase halogen reactant comprises a P—Cl bond. In some embodiments, the gas-phase halogen reactant is PCl₃. In some embodiments, the gas-phase halogen reactant is PCl₅. In some embodiments, the gas-phase halogen reactant is POCl₃. In some embodiments, the gas-phase halogen reactant is a dialkylphosphinic chloride (e.g. R₂POCl, R=alkyl). In some embodiments, the gas-phase halogen reactant is a diarylphosphinic chloride (e.g. R₂POCl, R=aryl). In some embodiments, the gas-phase halogen reactant is an alkylphosphonic dichloride (e.g. RPOCl₂, R=alkyl). In some embodiments, the gas-phase halogen reactant is an arylphosphonic dichloride (e.g. RPOCl₂, R=aryl).

In some embodiments, the gas-phase halogen reactant comprises a N—X bond. In some embodiments, the gas-phase halogen reactant comprises a N—Cl bond. In some embodiments, the gas-phase halogen reactant is N-chlorosuccinimide.

In some embodiments, the gas-phase halogen reactant comprises a O—X bond. In some embodiments, the gas-phase halogen reactant comprises a O—Cl bond. In some embodiments, the gas-phase halogen reactant is an alkyl hypochlorite. In some embodiments, the gas-phase halogen reactant is tert-butyl hypochlorite.

In accordance with examples of the disclosure, one or more gas-phase modifier reactants are introduced into the reaction chamber during the execution of process 100 of FIG. 1. In such examples, a gas-phase modifier reactant is employed in the cyclical etching process 106 during sub-step 108. The gas-phase modifier reactant is introduced into the reaction chamber and reacts with a halogenated surface of the transition metal oxide layer forming a modified surface as well as volatile by-products which are evacuated from the reaction chamber.

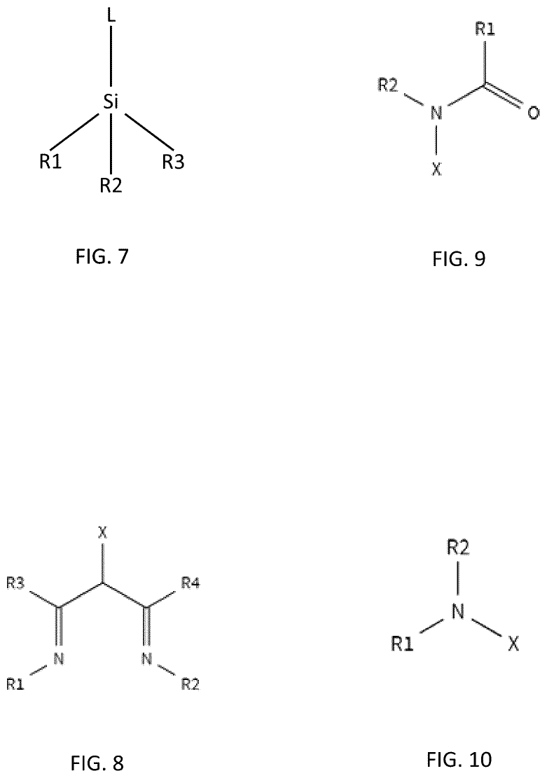

In some embodiments, the gas-phase halogen reactant has a formula SiR1R2R3L (as illustrated in FIG. 7), where all R groups (R1, R2, and R3) are independently selected from hydrogen, C1 to C6 alkyl groups and silyl groups, a halogen, or an alkoxy group of a formula OR4, where R4 is a C1 to C6 alkyl group, and where L is a ligand.

In some embodiments, at least one of R1 to R3 is hydrogen. In some embodiments, at least one of R1 to R3 is a C1 to C6 linear and branched alkyl. In some embodiments, at least one of R1 to R3 is a halogen selected from F, Cl, Br, or I. In some embodiments, at least one of R1 to R3 is an alkoxy group comprising one to six carbon atoms. In some embodiments at least one of R1 to R3 is a silyl, disilyl, or trisilyl group. In some embodiments, the R groups (R1, R2, and R3) are independently selected from hydrogen, methyl, ethyl,-SiH₃, —Si₂H₅, —Si₃H₇, fluorine, chlorine, bromine, iodine, methoxy, ethoxy, n-propoxy, isopropoxy, n-butoxy, sec-butoxy, or tert-butoxy.

In accordance with examples of the disclosure, R1 to R3 are alkyl groups. In such examples, R1 to R3 are methyl groups. In such examples, the gas-phase modifier reactant comprises a trialkylsilyl group. Further, in such examples, the trialkylsilyl group is a trimethylsilyl group (TMS).

In some embodiments, the gas-phase modifier reactant comprises a bidentate ligand.

In some embodiments, the gas-phase modifier reactant comprises a ligand with a hapticity greater than 1, greater than 2, greater than 3, greater than 4, or greater than 5.

In some embodiments, the gas-phase modifier reactant comprises a ligand (L) selected from a group consisting of cyclopentadienyl, beta-diketonate, amidinate, amidate, guanidinate, pyrazole, pyrrole, or dialkylamide.

In some embodiments, the gas-phase modifier reactant comprises a cyclopentadienyl (Cp) or substituted cyclopentadienyl ligand. In some embodiments, the substituent group on Cp comprises one or more of the following groups: methyl, ethyl, isopropyl, n-propyl, isobutyl, tert-butyl, n-butyl, sec-butyl, trimethylsilyl, pentyl, cyclopentyl, hexyl, cyclohexyl, 2-dimethylaminoethyl, 3-dimethylaminopropyl, 2-methoxyethyl, or 3-methoxypropyl.

In some embodiments, the gas-phase modifier reactant a beta-diketonate ligand. In some embodiments, the ligand is acetylacetonate (acac), 2,2,6,6-tetramethyl-3,5-heptanedionate (thd), or 1,1,1,5,5,5-hexafluoroacetylacetonate (hfac).

In some embodiments, the gas-phase modifier reactant comprises an amidinate or a guanidinate ligand. In some embodiments, the ligand is N,N′-di-tert-butylacetamidinate (tBu2AMD). In some embodiments, the ligand is N,N′-di-isopropylacetamidinate (iPr2AMD). In some embodiments, the ligand is N,N′-di-tert-pentylacetamidinate (tPn2AMD). In some embodiments, the ligand is N,N′-di-sec-butylacetamidinate (sBu2AMD). In some embodiments, the ligand is N,N′-di-tert-butylformamidinate (tBu2FMD). In some embodiments, the ligand is N,N′-di-isopropylformamidinate (iPr2FMD). In some embodiments, the ligand is N,N′-di-tert-pentylformamidinate (tPn2FMD). In some embodiments, the ligand is N,N′-di-sec-butylformamidinate (sBu2FMD).

In some embodiments, the gas-phase modifier reactant comprises a pyrazole, or substituted pyrazole, such as 3,5-dimethylpyrazole, for example. In some embodiments, the gas-phase modifier reactant comprises a pyrrole, or a substituted pyrrole, such as 2,3,4,5-tetramethylpyrrole, for example.

In some embodiments, the gas-phase modifier reactant comprises a beta-diketimine, as illustrated in FIG. 8, that upon loss of X can become a beta-diketiminate ligand. In some embodiments, R1, R2, R3, and R4 are independently selected from H, methyl, ethyl, n-propyl, isopropyl, n-butyl, sec-butyl, isobutyl, tert-butyl, n-pentyl, sec-pentyl, tert-pentyl, isopentyl, 2-methyl-2-pentyl, cyclopentyl, cyclohexyl, or phenyl. In some embodiments, X is a trialkyl silyl group. In some embodiments, the beta-diketiminate ligand is N,N′-(1,3-dimethyl-1,3-propanediylidene)bis [2-propanaminate]. In some embodiments, the beta-diketiminate ligand is N,N′-(1,3-dimethyl-1,3-propanediylidene)bis[2-methyl-2-propanaminate].

In some embodiments, the gas-phase modifier reactant comprises an amide, as illustrated in FIG. 9, that upon loss of X can become an amidate ligand. In some embodiments, R1 and R2 are independently selected from H, methyl, ethyl, n-propyl, isopropyl, n-butyl, sec-butyl, isobutyl, tert-butyl, n-pentyl, sec-pentyl, tert-pentyl, isopentyl, 2-methyl-2-pentyl, cyclopentyl, cyclohexyl, or phenyl. In some embodiments, X is a trialkyl silyl group. In some embodiments, the amidate ligand is N-methyl-acetamidate. In some embodiments, the amidate ligand is N-(1,1-dimethylethyl) acetamidate. In some embodiments, the amidate is N-(1-methylethyl) acetamidate.

In some embodiments, the gas-phase modifier reactant comprises an amine, as illustrated in FIG. 10, that upon the loss of X can become an amido ligand of the formula NR₂, where all —R groups are independently a C1 to C6 hydrocarbon, or hydrogen. In some embodiments, R1 and R2 are independently selected from H, methyl, ethyl, n-propyl, isopropyl, n-butyl, sec-butyl, isobutyl, tert-butyl, n-pentyl, sec-pentyl, tert-pentyl, isopentyl, 2-methyl-2-pentyl, cyclopentyl, cyclohexyl, or phenyl. In some embodiments, X is a trialkyl silyl group. In some embodiments, the amido ligand is dimethylamido. In some embodiments, the amido ligand is ethylmethylamido. In some embodiments, the ligand is diethylamido. In some embodiments, the ligand is diisopropylamido. In some embodiments, the ligand is pyrrolidine.

In some embodiments, the gas-phase modifier reactant comprises at least one N-trimethylsilyl-3,5,-dimethylpyrazole, N-trimethylsilyl-3,5,-di-tert-butylpyrazole, N-trimethylsilylpyrrole, and N-trimethylsilyl-2,3,4,5-tetramethylpyrrole.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method for etching a metal oxide layer on a surface of a substrate in a reaction chamber by a cyclical etching process, the cyclical etching process comprising one or more etching cycles, where each etching cycle comprising:
contacting the metal oxide layer with a gas-phase modifier reactant of a formula SiR1R2R3L, where all R groups (R1, R2, and R3) are independently selected from hydrogen, C1 to C6 alkyl groups and silyl groups, a halogen, or an alkoxy group of a formula OR4, where R4 is a C1 to C6 alkyl group, and where L is a ligand; and
contacting the metal oxide layer with a gas-phase halogen reactant.

2. The method of claim 1, wherein the ligand is selected from a group consisting of cyclopentadienyl, beta-diketonate, amidinate, amidate, guanidinate, pyrazole, pyrrole, or dialkylamide.

3. The method of claim 2, wherein the gas-phase modifier reactant comprises a trialkylsilyl group.

4. The method of claim 3, wherein the trialkylsilyl group is a trimethylsilyl group.

5. The method of claim 4, wherein the gas-phase modifier reactant comprises at least one of N-trimethylsilyl-3,5,-dimethylpyrazole, N-trimethylsilyl-3,5,-di-tert-butylpyrazole, N-trimethylsilylpyrrole, and N-trimethylsilyl-2,3,4,5-tetramethylpyrrole.

6. The method of claim 1, wherein the gas-phase halogen reactant comprises one or more of chlorine gas, hydrochloric acid, phosphorous pentachloride, phosphorous trichloride, phosphoryl chloride, thionyl chloride, sulfuryl chloride, disulfur dichloride, acetyl chloride, oxalyl chloride, N-chlorosuccinimide, and t-butyl hypochlorite.

7. The method of claim 1, wherein the metal oxide layer is a transition metal oxide selected from a group consisting of a zirconium oxide, a hafnium oxide, or a hafnium zirconium oxide.

8. The method of claim 1, wherein the metal oxide layer is initially contacted with the gas-phase halogen reactant prior to contacting the metal oxide layer with the gas-phase modifier reactant.

9. The method of claim 1, wherein the cyclical etching process is an atomic layer etching process.

10. A method for atomic layer etching a hafnium zirconium oxide layer, the method comprising:
seating a substrate comprising the hafnium zirconium oxide layer into a reaction chamber;
performing an atomic layer etching process comprising a plurality of repeated etching cycles, wherein each etching cycle comprises;
introducing into the reaction chamber a gas-phase modifier reactant comprising a trialkylsilyl group and a detachable group; and
introducing into the reaction chamber a gas-phase halogen reactant.

11. The method of claim 10, wherein the trialkylsilyl group is a trimethylsilyl group.

12. The method of claim 11, wherein the detachable group is a ligand selected from a group consisting of cyclopentadienyl, beta-diketonate, amidinate, amidate, guanidinate, pyrazole, pyrrole, or dialkylamide.

13. The method of claim 12, wherein the gas-phase modifier reactant comprises one or more f N-trimethylsilyl-3,5,-dimethylpyrazole, N-trimethylsilyl-3,5,-di-tert-butylpyrazole, N-trimethylsilylpyrrole, and N-trimethylsilyl-2,3,4,5-tetramethylpyrrole.

14. The method of claim 10, wherein the gas-phase halogen reactant comprises one or more of chlorine gas, hydrochloric acid, phosphorous pentachloride, phosphorous trichloride, phosphoryl chloride, thionyl chloride, sulfuryl chloride, disulfur dichloride, acetyl chloride, oxalyl chloride, N-chlorosuccinimide, and t-butyl hypochlorite.

15. The method of claim 10, wherein the hafnium zirconium oxide layer is initially contacted with the gas-phase halogen reactant prior to contacting the hafnium zirconium oxide layer with the gas-phase modifier reactant.

16. The method of claim 10, wherein the hafnium zirconium oxide layer has a zirconium content equal to or greater than 50 atomic-%.

17. A method of forming a hafnium zirconium oxide layer on a device structure, the method comprising:
depositing an amorphous hafnium zirconium oxide layer on a surface of the device structure supported within a reaction chamber;
thermally treating the amorphous hafnium zirconium oxide layer to form a crystalline hafnium zirconium oxide layer;
etching a portion of the crystalline hafnium zirconium oxide layer by a cyclical etching process comprising one or more etching cycles, where each etching cycle comprises:
contacting the crystalline hafnium zirconium oxide layer with a gas-phase modifier reactant of a formula SiR1R2R3L, where all R groups (R1, R2 and R3) are independently selected from hydrogen, C1 to C6 alkyl groups and silyl groups, a halogen, or an alkoxy group of a formula OR4, where R4 is a C1 to C6 alkyl group, and where L is a ligand; and
contacting the crystalline hafnium zirconium oxide layer with a gas-phase halogen reactant.

18. The method of claim 17, wherein the amorphous hafnium zirconium oxide layer is deposited by a conformal cyclical deposition process.

19. The method of claim 18, wherein the conformal cyclical deposition process comprises an atomic layer deposition process.

20. The method of claim 17, wherein the amorphous hafnium zirconium oxide layer has an average layer thickness equal to or greater than 5 nm.

21. The method of claim 17, wherein thermally treating the amorphous hafnium zirconium oxide layer comprises, annealing the amorphous hafnium zirconium oxide layer at a temperature between 300° C. and 500° C.

22. The method of claim 17, wherein etching a portion of the crystalline hafnium zirconium oxide layer by the cyclical etching process leaves a remaining portion of the crystalline hafnium zirconium oxide layer having an average layer thickness less than 5 nanometers.

23. The method of claim 22, wherein the remaining portion of the crystalline hafnium zirconium oxide layer has a capacitance equal to or greater than 100 fF/μm².

24. The method of claim 23, wherein the remaining portion of the crystalline hafnium zirconium oxide layer has a dielectric constant greater than 20.
